(19) United States
(12) Patent Application Publication
(10) Pub. No.: US 2011/0036404 A1
(43) Pub. Date: Feb. 17, 2011

(54) Photoelectric Conversion Device and Photovoltaic Power Generation Device

(75) Inventor: Kenji Tomita, Higashiomi-shi (JP)

Correspondence Address: DLA PIPER US LLP, 1999 AVENUE OF THE STARS, SUITE 400, LOS ANGELES, CA, 90067-6023, US

(73) Assignee: KYOCERA CORPORATION, Kyoto-shi, Kyoto (JP)

(21) Appl. No.: 12/988,623

(22) PCT Filed: Apr. 24, 2009
(86) PCT No.: PCT/JP2009/058186

§ 371 Date: Oct. 19, 2010

(30) Foreign Application Priority Data
Apr. 25, 2008 (JP) 2008-115299

(51) Int. Cl. H01L 31/042

(52) U.S. Cl. 136/258; 136/252

(57) ABSTRACT

An object of the present invention is to provide a photoelectric conversion device having a high power generation efficiency. A photoelectric conversion device includes a light-transmitting conductive part including a light incident surface and a light output surface, a semiconductor part formed on the light output surface, an anti-reflection coating formed on the semiconductor part, and a dye-sensitized photoelectric conversion body including a charge transport part and a dye that receives a charge from the charge transport part. The charge transport part is in contact with the anti-reflection coating. The anti-reflection coating has a bandgap larger than that of the semiconductor part.

### TECHNICAL FIELD

The present invention relates to a photoelectric conversion device and a photovoltaic power generation device.

### BACKGROUND ART

There are various forms of solar cells, such as a bulk crystal type silicon solar cell, a thin-film amorphous-silicon type solar cell using an amorphous silicon thin film, and the like. Additionally, a dye-sensitized solar cell is attracting attention, as a next-generation solar cell that aims at reduction of a silicon feedstock.

Also known is a solar cell (hereinafter also referred to as a “tandem type solar cell”) having a tandem type structure in which the dye-sensitized solar cell and the thin-film amorphous-silicon type solar cell are combined (for example, see Patent Document 1 stated below). Normally, the tandem type solar cell employs a structure in which a thin-film photoelectric conversion body made of an amorphous silicon thin film and a dye-sensitized photoelectric conversion body are put in layers in the mentioned order from the incident light side.

In such a tandem type solar cell, firstly, the thin-film photoelectric conversion body absorbs a short-wavelength light such as an ultraviolet light in incident sunlight, and performs photoelectric conversion thereon, and subsequently, the dye-sensitized photoelectric conversion body absorbs a long-wavelength light transmitted through the amorphous silicon photoelectric conversion body, and performs photoelectric conversion thereon. Combination of conversion efficiencies of both of the photoelectric conversion bodies provides the tandem type solar cell with a high photoelectric conversion efficiency. Moreover, since the thin-film photoelectric conversion body absorbs the short-wavelength light such as the ultraviolet light in the incident sunlight, a light directly received by the dye-sensitized photoelectric conversion body contains a small amount of strong short-wavelength lights such as the ultraviolet light, which can reduce a light-degradation of a dye in the dye-sensitized photoelectric conversion body.

However, in the tandem type solar cell disclosed in the Patent Document 1, there is a problem that, since a refractive index of the thin-film photoelectric conversion body and a refractive index of the dye-sensitized photoelectric conversion body are largely different from each other, a light reflection occurs at a boundary face between the thin-film photoelectric conversion body and the dye-sensitized photoelectric conversion body, which causes a photoelectric conversion loss.

### PRIOR ART DOCUMENT

### Patent Document

Patent Document 1: Japanese Patent Application Laid-Open No. 2005-158620

### DISCLOSURE OF THE INVENTION

A photoelectric conversion device according to an embodiment of the present invention includes a light-transmitting conductive part including a light incident surface and a light output surface, a semiconductor part formed on the light output surface, an anti-reflection coating formed on the semiconductor part, and a dye-sensitized photoelectric conversion body including a charge transport part and a dye that receives a charge from the charge transport part. The charge transport part is in contact with the anti-reflection coating. The anti-reflection coating has a bandgap larger than that of the semiconductor part.

In this photoelectric conversion device, a reflection occurring at a boundary face between the semiconductor part and the dye-sensitized photoelectric conversion body is reduced, so that the photoelectric conversion device can absorb more light and thus a power generation efficiency of the photoelectric conversion device can be improved.

A photoelectric conversion device according to another embodiment of the present invention includes a light-transmitting conductive part including a light incident surface and a light output surface, a semiconductor part formed on the light output surface, an anti-reflection coating formed on the semiconductor part, and a dye-sensitized photoelectric conversion body including a charge transport part and a dye that receives a charge from the charge transport part. The charge transport part is in contact with the anti-reflection coating. A difference between a HOMO level and a LUMO level of the dye is smaller than bandgaps of the semiconductor part and the anti-reflection coating.

In this photoelectric conversion device, a reflection occurring at a boundary face between the semiconductor part and the dye-sensitized photoelectric conversion body is reduced, so that the photoelectric conversion device can absorb more light and thus a power generation efficiency of the photoelectric conversion device can be improved.

Therefore, an object of the present invention is to provide a photoelectric conversion device and a photovoltaic power generation device having a high power generation efficiency.

### BRIEF DESCRIPTION OF THE DRAWINGS

FIG. 1 is a sectional view showing a structure of a photoelectric conversion device according to an embodiment of the present invention.

FIG. 2 shows a relationship between a light wavelength and a transmittance of a thin-film photoelectric conversion body in a photoelectric conversion device including no anti-reflection coating provided between the thin-film photoelectric conversion body and a dye-sensitized photoelectric conversion body.

FIG. 3 shows a relationship between a light wavelength and a transmittance of a thin-film photoelectric conversion body in a photoelectric conversion device including an anti-reflection coating provided between the thin-film photoelectric conversion body and a dye-sensitized photoelectric conversion body.

FIG. 4 shows an exemplary case where a photovoltaic power generation device configured with the photoelectric conversion device shown in FIG. 1 is applied to a residential photovoltaic power generation device.

### BEST MODE FOR CARRYING OUT THE INVENTION

### <1-1. Structure of Photoelectric Conversion Device>

Firstly, a structure of a photoelectric conversion device 100 according to an embodiment of the present invention will be described.

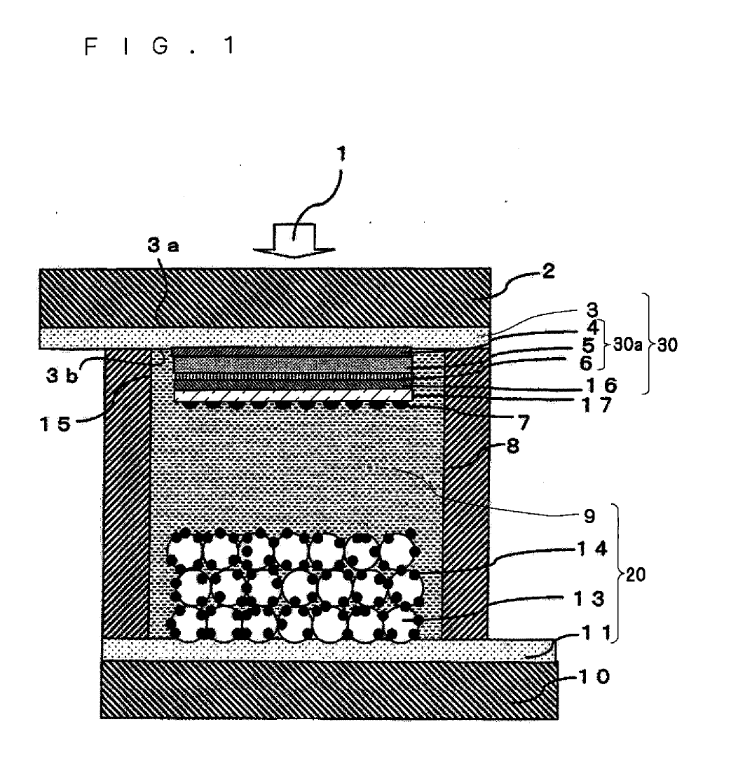

FIG. 1 is a sectional view showing a structure of the photoelectric conversion device 100 according to the embodiment of the present invention. The arrow 1 in FIG. 1 indicates incidence of a light (sunlight).

In outline, the photoelectric conversion device 100 mainly includes a light-transmitting substrate 2, a thin-film photoelectric conversion body 30 formed on the light-transmitting substrate 2, a dye-sensitized photoelectric conversion body 20, a light-transmitting substrate 10 formed on the dye-sensitized photoelectric conversion body 20, and a frame-shaped sealing member 8 which seals a part of the dye-sensitized photoelectric conversion body 20.

The thin-film photoelectric conversion body 30 includes a first light-transmitting conductive part 3, an amorphous semiconductor layer 30a, and a second light-transmitting conductive part 16, in the mentioned order from the light-transmitting substrate 2 side.

The amorphous semiconductor layer 30a is preferably formed of a thin-film type amorphous silicon semiconductor layer, and includes, for example, a first conductive type (for example, p-type) amorphous silicon semiconductor layer 4, an intrinsic type (i-type) amorphous silicon semiconductor layer 5, and a second conductive type (for example, n-type) amorphous silicon semiconductor layer 6.

The dye-sensitized photoelectric conversion body 20 includes, in the mentioned order from the light-transmitting substrate 10 side, a light-transmitting conductive part 11, a porous semiconductor layer 13 including a dye (a sensitizing dye) 14 adsorbed on a surface thereof, and further a charge transport part 9 (electrolyte layer) filled in a region surrounded by the thin-film photoelectric conversion body 30, the light-transmitting conductive part 11, and the sealing member 8.

An anti-reflection coating 17 is provided at an interface between the thin-film photoelectric conversion body 30 and the dye-sensitized photoelectric conversion body 20 (an interface between the second light-transmitting conductive part 16 and the charge transport part 9). The anti-reflection coating 17 is provided in order to reduce a light reflection occurring at a boundary face between the thin-film photoelectric conversion body 30 and the dye-sensitized photoelectric conversion body 20.

The photoelectric conversion device 100 may further include an island-shaped catalyst layer 7 provided on the anti-reflection coating 17. If the catalyst layer 7 is provided in the photoelectric conversion device 100, the charge transport part 9 is in contact with the anti-reflection coating 17 and the catalyst layer 7. The catalyst layer 7 is for facilitating transfer of charges between the thin-film photoelectric conversion body 30 and the dye-sensitized photoelectric conversion body 20.

### <1-2. Components of Photoelectric Conversion Device 100>

Next, respective components of the photoelectric conversion device 100 will be described.

### <Light-Transmitting Substrate>

The light-transmitting substrate 2 is a member that supports the first light-transmitting conductive part 3, and preferably has a thickness of approximately 0.1 to 5 mm.

The light-transmitting substrate 2 is made of a member having a translucency and capable of transmitting an incident light to the thin-film photoelectric conversion body 30 and the dye-sensitized photoelectric conversion body 20. As the member having translucency, a member made of a resin material, an inorganic material, a conductive resin material, an organic-inorganic hybrid material, or the like, is preferably used. Examples of the resin material include a PET (polyethylene terephthalate), a PEN (polyethylene naphthalate), a polyimide, a polycarbonate, and the like. Examples of the inorganic material include blue plate glass, soda glass, borosilicate glass, alkali-free glass, a light-transmitting ceramic, and the like. For example, when a member made of a glass material is used as the light-transmitting substrate 2, it is preferred to use reinforced glass, from the viewpoint of improvement of the mechanical strength of the photoelectric conversion device 100.

Moreover, from the viewpoint of prevention of a light reflection, it is preferred to provide anti-reflection coatings that control a refractive index and a porosity, on a light-incidence-side main face and a light-output-side main face of the light-transmitting substrate 2 (in FIG. 1, upper and lower surfaces of the light-transmitting substrate). Furthermore, from the viewpoint of design improvement, it is preferred to provide color films or the like on the light-incidence-side main face and the light-output-side main face of the light-transmitting substrate 2.

### <Thin-Film Photoelectric Conversion Body

Respective components of the thin-film photoelectric conversion body 30 will be described.

(First Light-Transmitting Conductive Part)

The first light-transmitting conductive part 3 serves to extract a current obtained by photoelectric conversion performed in the amorphous photoelectric conversion layer 30a. The first light-transmitting conductive part 3 is made of, for example, ITO (tin-doped indium oxide: indium-tin oxide), FTO (fluorine-doped tin oxide), or tin oxide.

The thickness of the first light-transmitting conductive part 3 is preferably 0.3 to 2 μm, for example. From the viewpoint of obtaining good FF characteristics of the photoelectric conversion device 100 by reducing the sheet resistance of the light-transmitting conductive part 3 and thereby reducing the series resistance of the photoelectric conversion device 100, it is preferred that the thickness of the first light-transmitting conductive part 3 is equal to or more than 0.3 μm. Moreover, from the viewpoint of enabling the first conductive type amorphous silicon semiconductor layer 4 to stably cover the entire surface of the first light-transmitting conductive part 3 by improving the smoothness of the surface of the first light-transmitting conductive part 3, it is preferred that the thickness of the first light-transmitting conductive part 3 is equal to or less than 2 μm.

This first light-transmitting conductive part 3 is formed as a layer on the light-transmitting substrate 2 by a CVD method or a sputtering method, or by spraying, for example.

(Amorphous Photoelectric Conversion Layer)

The amorphous photoelectric conversion layer 30a serves to perform so-called photoelectric conversion for converting incident light energy into electrical energy. It is preferred that the amorphous photoelectric conversion layer 30a has a pin junction, as in the present embodiment. Since the intrinsic type amorphous silicon semiconductor layer 5 is provided, a layer including micro crystallites or a layer including a hydrogenated amorphous silicon alloy can be used as at least one of the first conductive type amorphous silicon semiconductor layer 4 and the second conductive type amorphous silicon semiconductor layer 6. From the viewpoint of reducing a light loss by increasing translucency, it is preferred that the first conductive type amorphous silicon semiconductor layer 4 is made of a hydrogenated amorphous silicon carbide.

The thickness of the first conductive type amorphous silicon semiconductor layer 4 is preferably 50 to 200 Å for example, and more preferably 80 to 120 Å. From the viewpoint of making it easy to form an internal electric field in the amorphous photoelectric conversion layer 30a, it is preferred that the thickness of the first conductive type amorphous silicon semiconductor layer 4 is equal to or more than 50 Å. Additionally, from the viewpoint of suppressing a light loss, it is preferred that the thickness of the first conductive type amorphous silicon semiconductor layer 4 is equal to or less than 200 Å.

The thickness of the intrinsic type amorphous silicon semiconductor layer 5 is preferably 500 to 10000 Å (0.05 μm to 1 μm) for example, and more preferably 2000 to 8000 Å (0.2 μm to 0.8 μm). From the viewpoint of obtaining a good photocurrent, it is preferred that the thickness of the intrinsic type amorphous silicon semiconductor layer 5 is equal to or more than 2000 Å. From the viewpoint of making it easy to transmit a light to the dye-sensitized photoelectric conversion body 20 in the subsequent stage, it is preferred that the thickness of the intrinsic type amorphous silicon semiconductor layer 5 is equal to or less than 8000 Å.

The thickness of the second conductive type amorphous silicon semiconductor layer 6 is preferably 50 to 200 Å for example, and more preferably 80 to 120 Å. From the viewpoint of making it easy to form an internal electric field in the amorphous photoelectric conversion layer 30a, it is preferred that the thickness of the second conductive type amorphous silicon semiconductor layer 6 is equal to or more than 50 Å. From the viewpoint of suppressing a light loss, it is preferred that the thickness of the second conductive type amorphous silicon semiconductor layer 6 is equal to or less than 200 Å.

In the amorphous photoelectric conversion layer 30a formed with a lamination of these amorphous silicon semiconductor layers, a bandgap is approximately 1.8 eV. A light wavelength absorbed by the amorphous photoelectric conversion layer 30a is approximately 300 to 600 nm. Accordingly, the amorphous photoelectric conversion layer 30a hardly absorbs a long-wavelength light having a wavelength of 650 nm or more, that is, a light in a wavelength band absorbed by the dye-sensitized photoelectric conversion body 20 which will be described later. The amorphous photoelectric conversion layer 30a transmits therethrough such a long-wavelength light. It can be seen that, due to such characteristics of the amorphous photoelectric conversion layer 30a, the thin-film photoelectric conversion body 30 including the amorphous photoelectric conversion layer 30a forms a photoelectric conversion body suitable for forming a layered structure (tandem structure) with the dye-sensitized photoelectric conversion body 20.

Next, a method for forming a film of the amorphous photoelectric conversion layer 30a will be described. For example, the first conductive type amorphous silicon semiconductor layer 4 made of a p-type a-Si:H (H-doped amorphous silicon) is formed by a chemical vapor deposition using SiH₄ gas, H₂ gas, and B₂H₆ gas (B₂H₆ gas is diluted with H₂ to 500 ppm) as feed gas.

Also, for example, the intrinsic type amorphous silicon semiconductor layer 5 made of an i-type a-Si:H is formed by the chemical vapor deposition using SiH₄ gas and H₂ gas as feed gas.

Moreover, for example, the second conductive type amorphous silicon semiconductor layer 6 made of an n-type a-Si:H is formed by the chemical vapor deposition using SiH₄ gas, H₂ gas, and PH₃ gas (PH₃ gas is diluted with H₂ to 1000 ppm) as feed gas.

In the above-mentioned film formation method, by optimizing the flow rate of each feed gas, each amorphous silicon semiconductor layer can be formed into a predetermined thickness.

When the first conductive type amorphous silicon semiconductor layer 4, the intrinsic type amorphous silicon semiconductor layer 5, and the second conductive type amorphous silicon semiconductor layer 6 are formed, a suitable temperature of the light-transmitting substrate 2 is 150° C. to 300° C. for any of the layers, and more preferably 180° C. to 240° C.

A material of the amorphous photoelectric conversion layer 30a is not limited to the above-mentioned a-Si:H. Any material suffices as long, as the material mainly includes silicon. For example, the amorphous photoelectric conversion layer 30a may be formed using an a-SiCx:H (bandgap=2.1 to 2.3 eV), an a-SiNx:H (bandgap=2.1 to 2.3 eV), an a-SiOx:H (bandgap=2.1 to 2.3 eV), or a μc-SiCx:H (bandgap=1.9 to 2.1 eV). The bandgap can be obtained by a (hνα)²-vs-hν plot using a transmission absorption spectroscopy, for example.

(Second Light-Transmitting Conductive Part)

The second light-transmitting conductive part 16 serves to extract a current which is generated by the photoelectric conversion performed in the amorphous photoelectric conversion layer 30a. The second light-transmitting conductive part 16 preferably includes at least one of an indium oxide layer, a tin oxide layer, and an indium-tin oxide (ITO) layer, and more preferably includes either one of the ITO layer and the tin oxide layer. When the second light-transmitting conductive part 16 includes either one of the ITO layer and the tin oxide layer, the second light-transmitting conductive part 16 may be formed with a titanium oxide layer, an organic conductive layer, or the like, being laminated on the ITO layer, the tin oxide layer, or the like.

The thickness of the second light-transmitting conductive part 16 is preferably approximately 0.03 to 0.07 pm for example, and more preferably 0.04 to 0.06 μm. From the viewpoint of obtaining good FF characteristics of the photoelectric conversion device 100 by reducing the sheet resistance of the second light-transmitting conductive part 16 and thereby reducing the series resistance of the photoelectric conversion device 100, it is preferred that the thickness of the second light-transmitting conductive part 16 is equal to or more than 0.3 μm. Moreover, from the viewpoint of more effectively transmitting a light in a wavelength band that is effective for the power generation performed in the dye-sensitized photoelectric conversion body 20, it is preferred that the thickness of the second light-transmitting conductive part 16 is equal to or less than 0.07 μm.

Furthermore, from the viewpoint of light interference which will be described later, the aforementioned thickness of the second light-transmitting conductive part 16 is particularly effective when the refractive index of the amorphous photoelectric conversion layer 30a is approximately 3.5 and the refractive index of the second light-transmitting conductive part 16 made of the ITO or the like is approximately 1.9.

This second light-transmitting conductive part 16 is formed on the amorphous photoelectric conversion layer 30a by a CVD method or a sputtering method, or by spraying, for example.

The thin-film photoelectric conversion layer 30 thus formed absorbs a short-wavelength-side light (for example, a light having a wavelength of approximately 300 to 600 nm, hereinafter the same) in the incident light to perform the photoelectric conversion thereon, and transmits therethrough a long-wavelength-side light (for example, a light having a wavelength of approximately 600 to 900 nm, hereinafter the same).

<Anti-reflection coating>

The anti-reflection coating 17 serves to reduce a light reflection occurring at the interface between the thin-film photoelectric conversion body 30 and the dye-sensitized photoelectric conversion body 20, by using the light interference which will be described later. The anti-reflection coating 17 preferably includes at least one of an amorphous silicon carbide film, an amorphous silicon nitride film, and a titanium oxide film, for example. The anti-reflection coating 17 including such a material is conductive and able to efficiently transfer charges (current caused in power generation) extracted by the second light-transmitting conductive part 16, to the charge transport part 9. Conductive materials other than the above-mentioned materials may be used for the anti-reflection coating 17.

The thickness of the anti-reflection coating 17 is preferably approximately 0.01 to 0.07 μm, for example. From the viewpoint of obtaining an effective light interference effect by forming the anti-reflection. coating 17 so as to have a uniform thickness, it is preferred that the thickness of the anti-reflection coating 17 is equal to or more than 0.01 μm. Moreover, from the viewpoint of more effectively transmitting a light in a wavelength band that is effective for the power generation performed in the dye-sensitized photoelectric conversion body 20, it is preferred that the thickness of the anti-reflection coating 17 is equal to or less than 0.07 μm.

The anti-reflection coating 17 is formed using a material having a bandgap larger than the bandgap of the amorphous semiconductor layer 30a. The use of such a material makes it difficult for the anti-reflection coating 17 to absorb the long-wavelength-side light not absorbed by but transmitted through the amorphous semiconductor layer 30a. Therefore, the anti-reflection coating 17 can more effectively transmits therethrough the long-wavelength-side light while preventing a light reflection. For example, when the amorphous photoelectric conversion layer 30a is made of an amorphous silicon film having a bandgap of 1.8 eV, the anti-reflection coating 17 is preferably formed of an amorphous silicon carbide film or an amorphous silicon nitride film having a bandgap of 2.1 to 2.3 eV.

Next, a method for forming a film of the anti-reflection coating 17 will be described. The anti-reflection coating 17 made of an amorphous silicon carbide film and an amorphous silicon nitride film is formed on the amorphous photoelectric conversion layer 30a by a plasma CVD method or the like. The anti-reflection coating 17 made of a titanium oxide film is formed on the amorphous photoelectric conversion layer 30a by a sputtering method.

In the above-mentioned film formation step, a resistance value of the anti-reflection coating 17 can be easily controlled by adjusting the amount of doped impurities. That is, by adjusting the amount of doped impurities, the conductivity of the anti-reflection coating 17 can be easily increased. if the conductivity of the anti-reflection coating 17 is increased in this manner, the series resistance at the time when the charges (corresponding to the power generation current) occurring in the thin-film photoelectric conversion body 30 transfer to the charge transport part 9 is reduced, so that the charges extracted by the second light-transmitting conductive part 16 can be more efficiently transferred to the charge transport part 9.

Specifically, the resistance value of the anti-reflection coating 17 can be lowered by doping boron or phosphorus when the anti-reflection coating 17 made of an amorphous silicon carbide film or an amorphous silicon nitride film is formed by using the plasma CVD method. Also, the resistance value of the anti-reflection coating 17 can be lowered by doping niobium when the anti-reflection coating 17 made of a titanium oxide film is formed by using the sputtering method.

Next, the light interference caused by the anti-reflection coating 17 will be described. The light interference referred to herein means an effect that when the film thickness is equal to or less than the wavelength order of a light, a transmitted light and a reflected light interfere with each other so as to enhance and/or weaken each other.

For example, when the anti-reflection coating 17 is made of a single-layer film, interference of a reflected wave occurring at both interfaces (an incident surface and an output surface) of the single-layer film is considered, and the sum of the reflected wave and a transmitted wave is obtained to obtain the amplitude reflectance and the transmittance of the single-layer film.

Based on Snell's law and Fresnel coefficients, the amplitude reflectance is given by a formula having a cosine function, and the amplitude reflectance vibrates in accordance with the refractive index, the wavelength, and the film. thickness. That is, the reflectance has the minimum value in accordance with the values of the refractive index, the wavelength, and the film thickness. Thus, a design for reducing the reflectance can be obtained by determining an objective wavelength to be transmitted, the refractive index of a film used as the anti-reflection coating 17, and the film thickness of the anti-reflection coating 17. Specifically, when the anti-reflection coating 17 satisfies the relationship of λ (wavelength)=n (refractive index)×d (film thickness), a light having the wavelength λ at that time has the minimum reflectance.

In this manner, by adjusting the refractive index and the film thickness of the anti-reflection coating 17, the reflectance of a light having a desired wavelength can be reduced in light reflections occurring at the interface between the thin-film photoelectric conversion body 30 and the dye-sensitized photoelectric conversion body 20. Accordingly, for a light having the wavelength that is transmitted through the thin-film photoelectric conversion body 30 but absorbed by the dye-sensitized photoelectric conversion body 20, the anti-reflection coating 17 having the refractive index and the film thickness that satisfy the above-mentioned relationship is formed, to thereby reduce the reflectance of the light in the wavelength band absorbed by the dye-sensitized photoelectric conversion body 20.

When the anti-reflection coating 17 is made of a multi-layer film, the film thickness and the refractive index of each layer of the multi-layer film may be obtained by a known optical calculation method for a multi-layer film, such as a method of performing sequential computations using effective Fresnel coefficients or a method of obtaining a product of an admittance matrix.

In this manner, by designing the film thickness and the refractive index of each film of the anti-reflection coating 17, each film can be set so as to reduce the reflectance in a certain wavelength. That is, each film reduces the reflectance of a light in a desired wavelength, so that the reflectance of a light in a wide wavelength range can be reduced in the light reflection occurring in the interface between the thin-film photoelectric conversion body 30 and the dye-sensitized photoelectric conversion body 20.

It is preferred that a transparent conductive film having a higher refractive index than the refractive indexes of the second light-transmitting conductive part 16 and the charge transport part 9 is used for the anti-reflection coating 17. The use of the transparent conductive film having such a refractive index increases the light interference effect to improve an anti-reflection efficiency of the anti-reflection coating 17, and thus the light reflection occurring between the second light-transmitting conductive part 16 and the charge transport part 9 can be more reduced. This effect of the improvement of the anti-reflection efficiency can be particularly suitably obtained when the refractive index of the anti-reflection coating 17 is 2.6 to 3.5, the refractive index of the second light-transmitting conductive part 16 made of ITO is approximately 1.9, and the refractive index of the charge transport part 9 is approximately 1.3, for example.

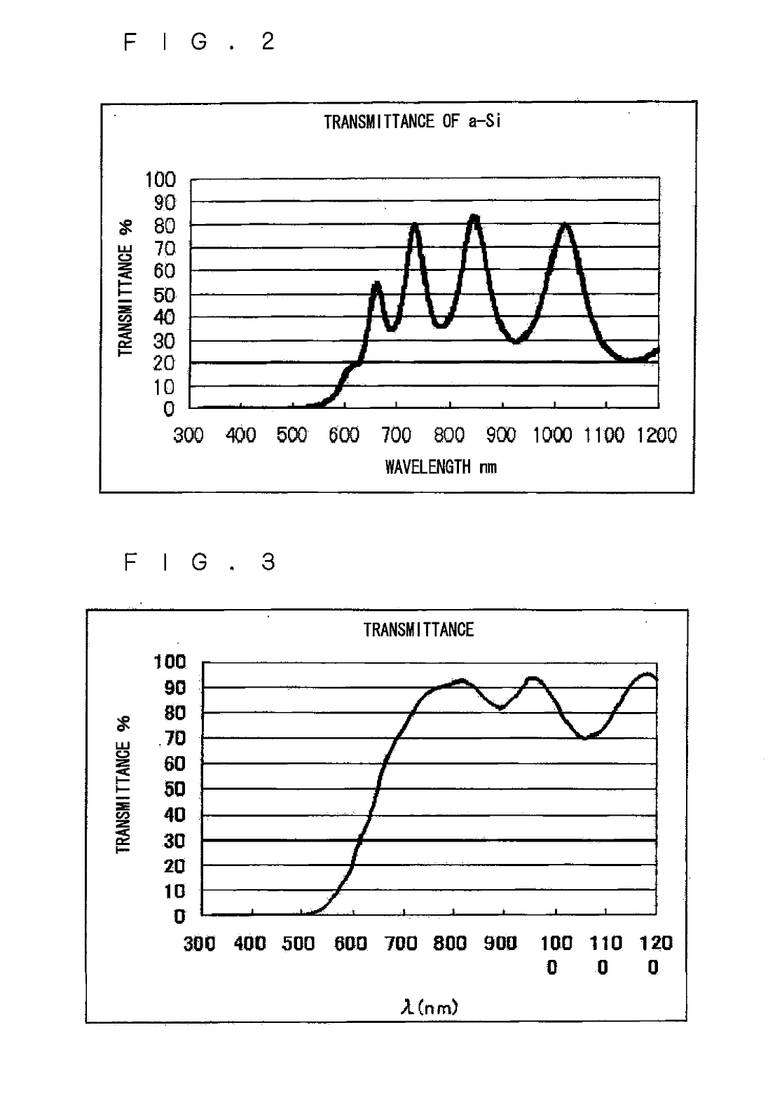

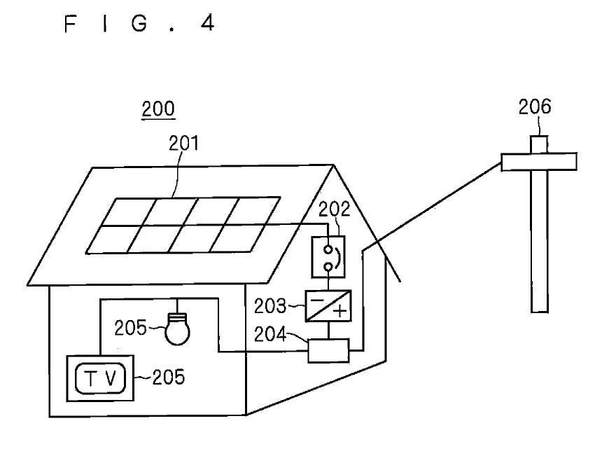

Next, a description will be given of a relationship between the light transmittance of the thin-film photoelectric conversion layer 30 and whether there are the second light-transmitting conductive part 16 and the anti-reflection coating 17 or not FIG. 2 is a graph showing a relationship between the light wavelength and the transmittance of the thin-film photoelectric conversion layer 30 in a photoelectric conversion device not including the second light-transmitting conductive part 16 and the anti-reflection coating 17. FIG. 3 is a graph showing a relationship between the light wavelength and the transmittance of the thin-film photoelectric conversion layer 30 in the photoelectric conversion device 100 including the second light-transmitting conductive part 16 and the anti-reflection coating 17. In FIG. 2 and FIG. 3, the amorphous photoelectric conversion layer 30a has a thickness of 0.63 μm and a refractive index of 3.5, the second light-transmitting conductive part 16 is made of ITO having a thickness of 50 nm and a refractive index of 1.9, and the anti-reflection layer 17 is made of amorphous silicon carbide having a thickness of 13 nm.

From FIG. 2 and FIG. 3, it can be seen that when the photoelectric conversion device 100 has the second light-transmitting conductive part 16 and the anti-reflection coating 17, the transmittance of a light in a wavelength of 600 to 1000 nm, which is a wavelength band contributing to the power generation in the dye-sensitized photoelectric conversion body 20, is greatly improved.

In other words, by providing the anti-reflection coating 17 between the thin-film photoelectric conversion body 30 and the dye-sensitized photoelectric conversion body 20, a reflection of a light in the wavelength band contributing to the power generation in the dye-sensitized photoelectric conversion body 20 is reduced. Thus, the light in the wavelength band contributing to the power generation in the dye-sensitized photoelectric conversion body 20 can be more effectively transmitted to the dye-sensitized photoelectric conversion body 20, and therefore the conversion efficiency of the photoelectric conversion device 100 can be improved.

### <Catalyst Layer>

The catalyst layer 7 is formed on the anti-reflection coating 17, in the shape of a plurality of islands. The catalyst layer 7 serves to facilitate the transfer of charges between the charge transport part (electrolyte layer) 9 and the amorphous semiconductor layer 30a. The catalyst layer 7 is preferably made of platinum, palladium, rhodium, carbon, or polythiophene, for example. By using these materials, the transfer of charges between the charge transport part 9 and the thin-film photoelectric conversion body 30 can be made easier, and the overvoltage (voltage applied at the initial stage of driving of the photoelectric conversion device) can be made smaller.

The thickness of the catalyst layer 7 is preferably approximately 0.5 to 20 nm. From the viewpoint of obtaining a good catalytic effect, it is preferred that the thickness of the catalyst layer 7 is equal to or more than 0.5 nm. From the viewpoint of suppressing a decrease in the amount of transmitted light, it is preferred that the thickness of the catalyst layer 7 is equal to or less than 20 nm.

The catalyst layer 7 is formed by the sputtering method or the like. In a case of the sputtering method, the catalyst layer 7 can be formed so as to have an island-shaped structure, by utilizing film formation characteristics that if a film to be formed is extremely thin, the film grows into an island shape.

In the present embodiment, the second light-transmitting conductive part 16 has conductivity. Therefore, even when the thin-film photoelectric conversion body 30 is incorporated in the same cell as the dye-sensitized photoelectric conversion body 20 is, generation of an extra electric field in the charge transport part 9 which causes separation or the like of the catalyst layer 7 can be suppressed. Thus, even when the thin-film photoelectric conversion body 30 is incorporated in the same cell as the dye-sensitized photoelectric conversion body 20 is, the catalyst layer 7 with high reliability can be obtained.

### <Sealing, Member>

The sealing member 8 is a frame body for sealing the dye-sensitized photoelectric conversion body 20, the amorphous semiconductor layer 30a, and the like, from the outside. For example, a resin adhesive or an inorganic adhesive is used as the sealing member 8. As the resin adhesive, polyethylene, polypropylene, epoxy resins, fluorine resins, silicon resins, and the like, may be mentioned. As the inorganic adhesive, a glass frit, a ceramic, and the like, may be mentioned.

The height (thickness) of the sealing member 8 is determined by the thin-film photoelectric conversion body 30, the dye-sensitized photoelectric conversion body 20, the anti-reflection coating 17, and the catalyst layer 7, which are objects to be sealed. The sealing member 8 has a thickness of approximately 0.06 to 1000 μm, for example.

For example, the sealing member 8 made of a resin material can be formed by placing the resin material so as to have a frame shape between the first light-transmitting conductive part 3 and the second light-transmitting conductive part 11 and then curing the resin material.

In this manner, when the thin-film photoelectric conversion body 30 and the dye-sensitized photoelectric conversion body 20 are configured to be sealed by the sealing member 8, the photoelectric conversion device has high durability and reliability against light irradiation and high-temperature heating. This can effectively suppress leakage of the charge transport part 9 from the photoelectric conversion device, which may be caused by the light irradiation and high-temperature heating.

### <Dye-Sensitized Photoelectric Conversion Body>

Next, respective components of the dye-sensitized photoelectric conversion body 20 will be described.

(Light-Transmitting Substrate)

The light-transmitting substrate 10 supports the light-transmitting conductive part 11. The material and the shape of the light-transmitting substrate 10 may be the same as those of the light-transmitting substrate 2.

(Light-Transmitting Conductive Part)

The light-transmitting conductive part 11 serves to extract a current obtained by a dye-sensitized mechanism. The material and the shape of the light-transmitting conductive part 11 may be the same as those of the first light-transmitting conductive part 2.

(Charge Transport Part)

The charge transport part 9 serves to transport charges received from the second light-transmitting conductive part 16 and the anti-reflection coating 17, to the porous semiconductor layer 13. From the viewpoint of improving the photoelectric conversion efficiency, it is preferred that a liquid-state electrolyte or a gel-state electrolyte which is excellent in charge transport characteristics is used for the charge transport part 9.

The charge transport part 9 may be made of a solid electrolyte, a conductive polymer, or an organic-molecule electron transport agent, for example. As the solid electrolyte, a polymer electrolyte and the like may be mentioned. As the conductive polymer, polythiophene, polypyrrole, polyphenylene vinylene, and the like, may be mentioned. As the organic-molecule electron transport agent, a fullerene derivative, a pentacene derivative, a perylene derivative, a triphenyldiamine derivative, and the like, may be mentioned.

The charge transport part 9 made of the above-mentioned material includes iodine/iodide salt, bromine/bromide salt, a cobalt complex, potassium ferrocyanide, or the like. Here, the expression “iodine/iodide salt” indicates that iodine and iodide salt reversibly change into each other in the charge transport part 9.

The thickness of the charge transport part 9 is preferably approximately 0.01 to 500 μm, for example. From the viewpoint of reducing the possibility that the positive side (amorphous semiconductor layer 30a side) and the opposite side (dye-sensitized photoelectric conversion body 20 side) are brought into contact to form a short circuit, it is preferred that the thickness of the charge transport part 9 is equal to or more than 0.01 μm. From the viewpoint of improving the photoelectric conversion efficiency of the photoelectric conversion device 100 by reducing a resistance component of the charge transport part 9, it is preferred that the thickness of the charge transport part 9 is equal to or less than 500 μm.

(Porous Semiconductor Layer)

The porous semiconductor layer 13 serves to support the later-described dye (sensitizing dye) 14 within pores. It is preferred that the porous semiconductor layer 13 has a shape having a large surface area. Examples of the shape of the porous semiconductor layer 13 having a large surface area include an aggregation of particles or an aggregation of linear objects. As the linear objects, needle-like objects, tubular objects, columnar objects, or the like, may be mentioned. It is preferred that the particles or the needle-like objects are fine particles or fine linear objects, because an area of contact between the objects is increased and an electrical resistance of the porous semiconductor layer 13 is reduced. The average particle diameter of the fine particles or the average line size of the fine linear objects is preferably 5 to 500 nm, and more preferably 10 to 200 nm. From the viewpoint of easiness of a fine processing step, it is preferred that the average particle diameter of the fine particles or the average line size of the fine linear objects is equal to or more than 5 nm. From the viewpoint of reducing the electrical resistance of the porous semiconductor layer 13 so that a photocurrent can be extracted in a good manner, it is preferred that the average particle diameter of the fine particles or the average line size of the fine linear objects is equal to or less than 500 nm.

A semiconductor layer provided with pores in this manner has a large surface area to support (adsorb) a larger amount of the dye 14, and therefore can more efficiently absorb the long-wavelength light transmitted through the thin-film photoelectric conversion body 30 and perform photoelectric conversion thereon, Due to such characteristics, the porous semiconductor layer 13 is adopted in the dye-sensitized photoelectric conversion body 20.

As a material of the porous semiconductor layer 13, the most suitable is titanium oxide (TiO₂). Other preferable materials include a metal oxide semiconductor of at least one of metal elements such as titanium (Ti), zinc (Zn), tin (Sn), niobium (Nb), indium (In), yttrium (Y), lanthanum (La), zirconium (Zr), tantalum (Ta), hafnium (Hf), strontium (Sr), barium (Ba), calcium (Ca), vanadium (V), tungsten (W), and the like. Additionally, one or more of non-metal elements such as nitrogen (N), carbon (C), fluorine (F), sulfur (S), chlorine (CI), phosphorus (P), and the like, may be contained. The reason why the use of the above-mentioned materials is preferred is that any of the materials has an electronic energy bandgap in a range of 2 to 5 eV which is larger than the energy of a visible light Moreover, for the porous semiconductor layer 13, an n-type semiconductor is preferred whose conduction band in an electronic energy level is lower than a conduction band of the dye 14.

The porous semiconductor layer 13 is preferably made of an n-type oxide semiconductor layer or the like in which many fine pores are provided. The diameter of the pore is preferably approximately 10 to 40 nm. The photoelectric conversion efficiency of this porous semiconductor layer 13 reaches the peak when the diameter of the pore is 22 nm.

From the viewpoint of improving the photoelectric conversion efficiency of the photoelectric conversion device 100 by performing penetration and adsorption of the dye 14 in a good manner, it is preferred that the diameter of the pore of the porous semiconductor layer 13 is equal to or more than 10 nm. From the viewpoint of increasing the amount of adsorption of the dye 14 by increasing a specific surface area of the porous semiconductor layer 13, it is preferred that the diameter of the pore of the porous semiconductor layer 13 is equal to or less than 40 nm.

The porosity of the porous semiconductor layer 13 is preferably 20 to 80%, and more preferably 40 to 60%. By providing such porousness, a surface area serving as a photosensitive electrode layer can be increased more than thousand times as compared with a dense body, so that the light absorption, the photoelectric conversion, and the electronic conduction can be efficiency performed.

The porosity of the porous semiconductor layer 13 can be obtained by the following method. Firstly, an adsorption isotherm curve of a specimen is obtained by a nitrogen gas adsorbing method using a gas adsorption measuring apparatus, and then the volume of the pores is obtained by a BJH (Barrett-Joyner-Halenda) method, a CI (Chemical Ionization) method, a DH (Dollimore-Heal) method, or the like. The porosity of the porous semiconductor layer 13 is obtained based on the volume of the pores and the particle density of the specimen.

The porous semiconductor layer 13 may be made of a sintered body of oxide-semiconductor fine particles. In this case, it is preferred that the porous semiconductor layer 13 is structured such that the average particle diameter of the oxide-semiconductor fine particles gradually decreases from the light-transmitting substrate 10 side toward the catalyst layer 7 side. For example, it is preferred that the porous semiconductor layer 13 is made up of a lamination of two layers having different average particle diameters of the oxide-semiconductor fine particles. Specifically, the oxide-semiconductor fine particles having a large average particle diameter are provided at the light-transmitting substrate 10 side, and the oxide-semiconductor fine particles (scattered particles) having a small average particle diameter are provided at the catalyst layer 7 side. Because of such a structure, the porous semiconductor layer 13 having a large average particle diameter causes a light trapping effect due to a light scattering and a light reflection, to improve the photoelectric conversion efficiency.

For example, oxide-semiconductor fine particles having an average particle diameter of approximately 20 nm may be used as the oxide-semiconductor fine particles having a small average particle diameter, and a mixture of oxide-semiconductor fine particles having an average particle diameter of approximately 20 nm and oxide-semiconductor fine particles having an average particle diameter of approximately 180 nm being mixed at a weight ratio of 70 wt% and 30 wt%, respectively, may be used as the oxide-semiconductor fine particles having a large average particle diameter. By changing the weight ratio, the average particle diameter, the film thickness of each layer, an optimal light trapping effect can be obtained. Moreover, the average particle diameter may be gradually decreased from the light-transmitting substrate 10 side to the catalyst layer 7 side, by increasing the number of layers from two to three or more or by forming these layers by application so as not to form a boundary therebetween.

The thickness of the porous semiconductor layer 13 is preferably 0.1 to 50 μm for example, and more preferably 1 to 20 μm. From the viewpoint of increasing the amount of adsorption of the dye 14 to increase the photoelectric conversion efficiency, it is preferred that the thickness of the porous semiconductor layer 13 is equal to or more than 0.1 μm. From the viewpoint of increasing the light transmittance to facilitate the incidence of a light onto the dye inside the porous semiconductor layer 13, it is preferred that the thickness of the porous semiconductor layer 13 is equal to or less than 50 μm.

When such a porous semiconductor layer 13 is used, the dye-sensitized photoelectric conversion body 20 made of this porous semiconductor layer 13 including the dye 14 adsorbed thereon obtains a concavo-convex surface. This improves the light trapping effect, and thus the photoelectric conversion efficiency can be further increased.

It is preferred that a ultrathin dense layer (having a thickness of approximately 5 μm) made of an n-type oxide semiconductor is provided between the porous semiconductor layer 13 and the light-transmitting conductive part 11. If such a dense layer is provided, a reverse current between the porous semiconductor layer 13 and the light-transmitting conductive part 11 is suppressed, to improve the photoelectric conversion efficiency.

Next, a method for manufacturing the porous semiconductor layer 13 will be described.

For example, the porous semiconductor layer 13 made of titanium oxide can be formed as follows. Firstly, acetylacetone is added to a TiO₂ anatase powder and the mixture is kneaded with deionized water to prepare a paste of titanium oxide stabilized with a surfactant. The paste thus prepared is applied onto the light-transmitting conductive layer 11 at a constant speed using a doctor blade method or a barcode method and then subjected to a heat treatment and sintered in atmospheric air at 300 to 600° C., preferably at 400 to 500° C., for 10 to 60 minutes, preferably for 20 to 40 minutes. This manufacturing method is preferred because of its simplicity and convenience.

The porous semiconductor layer 13 may also be formed by a low-temperature growth process. As the low-temperature growth process, an electrodeposition method, a cataphoretic electrodeposition method, a hydrothermal synthesis method, or the like, is preferably adopted. Additionally, it is preferred that a microwave treatment, a plasma treatment using a CVD method, a thermal catalyst treatment, a UV irradiation treatment, or the like, is performed as a post-treatment which is performed for the purpose of improving electron transport characteristics. Particularly, the porous semiconductor layer 13 formed by the low-temperature growth process is preferably made of a porous ZnO layer formed by the electrodeposition method, a porous TiO₂ layer formed by the cataphoretic electrodeposition method, or the like.

Moreover, the porous surface of the porous semiconductor layer 13 is preferably subjected to a TiCl₄ treatment The TiCl₄ treatment is, for example, a treatment of firstly immersing in a TiCl₄ solution for 13 hours, then washing with water, and then sintering at 450° C. for 30 minutes. As a result, electron conductivity within the porous semiconductor layer 13 is improved, thus improving the photoelectric conversion efficiency.

(Dye)

The dye 14 serves to absorb the long-wavelength side light having a wavelength of approximately 600 to 900 nm, and transfers excited electrons to the porous semiconductor layer 13. As the dye 14, preferably used is, for example, ruthenium-tris type transition metal complex, ruthenium-bis type transition metal complex, osmium-tris type transition metal complex or osmium-bis type transition metal complex, a multinuclear complex, a ruthenium-cis-diaqua-bipyridyl complex, phthalocyanine, porphyrin, a polycyclic aromatic compound, or a xanthene-based dye such as rhodamine B.

In order that the porous semiconductor layer 13 efficiently adsorbs the dye 14 thereon, it is effective that the dye 14 contains at least one of carboxyl group, sulfonyl group, hydroxamic acid group, alkoxy group, aryl group, or phosphoryl group, as a substituent. Here, the substituent preferably enables strong chemical adsorption of the dye 14 to the porous semiconductor layer 13 and easy transfer of charges from the dye 14 in an excitation state to the porous semiconductor layer 13.

As a method for adsorbing the dye 14 to the porous semiconductor layer 13, a method of immersing the porous semiconductor layer 13 in a solution containing the dye 14 dissolved therein may be mentioned, for example.

As a solvent of the solution into which the dye 14 is dissolved, for example, alcohols such as ethanol; ketones such as acetone; ethers such as diethylether; and nitrogen compounds such as acetonitrile are used alone or a mixture of two or more kinds of them is used. The concentration of the dye 14 in the solution is preferably in the range from about 5×10⁻⁵ to 2×10⁻³ mol/l.

There are no restrictions on temperature conditions of the solution and the atmosphere in the case of adsorbing the dye 14 to the porous semiconductor layer 13. For example, the adsorption can be performed under the atmospheric pressure or in a vacuum, at the room temperature or under a heating condition. A time for the adsorption of the dye 14 can be appropriately adjusted according to kinds of the dye 14 and the solution, the concentration of the solution, the circulating amounts of the dye 14 and the solution, and the like. Consequently, the dye 14 can be adsorbed to the porous semiconductor layer 13.

Next, an energy gap of the dye will be described. The dye 14 irradiated with a light absorbs light energy, and transits from the ground state to the excited state. An energy gap at this time corresponds to an energy difference between a HOMO and a LUMO (hereinafter also referred to as “HOMO-LUMO” energy). A ground energy level of the dye 14 can be qualitatively considered to be a HOMO level, and an excited energy level of the dye 14 can be qualitatively considered to be a LUMO level. Here, the HOMO (Highest Occupied Molecular Orbital) means an orbital with the highest energy among molecular orbitals occupied by an electron, and the LUMO (Lowest Unoccupied Molecular Orbital) means an orbital with the lowest energy among molecular orbitals unoccupied by an electron.

For example, it is preferred that the dye-sensitized photoelectric conversion body 20 which absorbs the long-wavelength side light has a HOMO-LUMO energy of 0.4 to 2.4 eV.

In such a case, the HOMO-LUMO energy of the dye-sensitized photoelectric conversion body 20 is smaller than the bandgap energy of the thin-film photoelectric conversion body 30. Therefore, in the light incident on the photoelectric conversion device 100, the short-wavelength side light is subjected to the photoelectric conversion by the thin-film photoelectric conversion body 30, and the long-wavelength side light is subjected to the photoelectric conversion by the dye-sensitized photoelectric conversion body 20.

As described above, in the present embodiment, since the anti-reflection coating 17 is provided between the thin-film photoelectric conversion body 30 and the dye-sensitized photoelectric conversion body 20, a reflection occurring at the boundary face between the thin-film photoelectric conversion body 30 and the dye-sensitized photoelectric conversion body 20 is reduced, so that the photoelectric conversion device 100 can absorb more light, to exert a high power generation efficiency.

### <1-3. Photovoltaic Power Generation Device>

A photovoltaic power generation device 200 may be configured such that power generated by using the above-described photoelectric conversion device 100 is supplied to various loads such as a light-emitting device and an illumination device. FIG. 4 shows an exemplary case where the photovoltaic power generation device 200 configured with the photoelectric conversion device 100 is applied to a residential photovoltaic power generation device. An array 201 of modules each including the photoelectric conversion device 100 being arranged and wired is placed on a roof of a house. DC power caused by power generation in the photoelectric conversion device 100 and extracted from the array 201 is given from a DC switch 202 to an inverter device 203. In the inverter device 203, the DC power is converted into AC. The AC power obtained as a result of the conversion is supplied from a distribution board 204 to loads 205 such as the illumination device. Power is also supplied to a domestic electrical system from a commercial power system 206 via the distribution board 204, so that when power supplied from the photoelectric conversion device 100 is scarce, for example, at night, the power supplied from the power system 206 can be used.

By configuring the photovoltaic power generation device 200 in this manner, a power generation capacity is improved by the photoelectric conversion device 100 of the present embodiment having the high photoelectric conversion efficiency, and therefore a high power generation efficiency can be obtained for a long time.

### EXAMPLE

The above-described photoelectric conversion device 100 was prepared by the following procedure.

Firstly, a glass substrate (having a size of 1 cm×2 cm) including the first light-transmitting conductive part 3 (an ITO layer with a thickness of 350 nm and a sheet resistance of 10 Ω/□) formed on one main surface thereof was prepared as the light-transmitting substrate 2.

Then, by using a plasma CVD apparatus, the first conductive type amorphous silicon semiconductor layer 4 made of p-type a-Si:H, the intrinsic type amorphous silicon semiconductor layer 5 made of i-type a-Si:H, and the second conductive type amorphous silicon semiconductor layer 6 made of n-type a-Si:H were sequentially and continuously deposited on the first light-transmitting conductive part 3 in a vacuum.

The first conductive type amorphous silicon semiconductor layer 4 was formed by using SiH₄ gas and B₂H₆ gas (diluted with H₂) as feed gas with flow rates thereof being 2.7 sccm and 9 sccm, respectively, and depositing the p-type a-Si:H so as to have a thickness of 100 Å (0.01 μm) on the first light-transmitting conductive part 3.

The intrinsic type amorphous silicon semiconductor layer 5 was formed by using SiH₄ gas and H₂ gas as feed gas with flow rates thereof being 5 sccm and 20 sccm, respectively, and depositing the i-type a-Si:H so as to have a thickness of 6000 A (0.6 μm) on the first conductive type amorphous silicon semiconductor layer 4.

The second conductive type amorphous silicon semiconductor layer 6 was formed by using SiH₄ gas, H₂ gas, and PH₃ gas (diluted with H₂) as feed gas with flow rates thereof being 2.7 sccm, 37 sccm, and 2.8, sccm, respectively, and depositing the n-type a-Si:H so as to have a thickness of 200 Å (0.02 μm) on the intrinsic type amorphous silicon semiconductor layer 5.

In any of the cases of forming the first conductive type amorphous silicon semiconductor layer 4, the intrinsic type amorphous silicon semiconductor layer 5, and the second conductive type amorphous silicon semiconductor layer 6, the temperature of the glass substrate was 20.0° C.

In the above-described procedure, the amorphous semiconductor layer 30a which has a thickness of 0.63 μm and a refractive index of 3.5 and which is made up of the first conductive type amorphous silicon semiconductor layer 4, the intrinsic type amorphous silicon semiconductor layer 5, and the second conductive type amorphous silicon semiconductor layer 6, was formed.

Then, as the second light-transmitting conductive part 16, an ITO layer having a refractive index of 1.9 was formed so as to have a thickness of 50 nm. By the plasma CVD method, the anti-reflection coating 17 was formed by using SiH₄ gas, H₂ gas, B₂H₆ gas (diluted with H₂), and CH₄ as feed gas with flow rates thereof being 10 sccm, 10 sccm, 2 sccm, and 10 sccm, respectively, and depositing amorphous silicon carbide so as to have a thickness of 130 Å (0.013 μm) on the second light-transmitting conductive part 16.

When the light wavelength and the light transmittance were measured before forming the second light-transmitting conductive part 16 and the anti-reflection coating 17, the light wavelength and the light transmittance of the thin-film photoelectric conversion body 30 had a relationship of the transmittance characteristics shown in the graph of FIG. 2. On the other hand, when the light wavelength and the light transmittance were measured after forming the second light-transmitting conductive part 16 and the anti-reflection coating 17, the light wavelength and the light transmittance of the thin-film photoelectric conversion body 30 had a relationship of the transmittance characteristics shown in the graph of FIG. 3. That is, in the wavelength of 600 to 1200 nm, the transmittance of the thin-film photoelectric conversion body 30 was considerably improved. The transmittance was measured by UV-VIS-NIR Spectrophotometer V-600 manufactured by JASCO Corporation.

Then, the catalyst layer 7 was formed by depositing a Pt layer so as to have a thickness of 0.01 μm on the anti-reflection coating 17 with the use of a sputtering apparatus. Here, since the Pt layer is thin, the Pt layer has a high resistance, and thus the sheet resistance of a Pt layer separately and similarly formed on the glass substrate could not be measured.

Then, a glass substrate (having a size of 1 cm×2 cm) including the light-transmitting conductive layer 11 (SnO₂:F (an FTO layer) with a thickness of 800 nm and a sheet resistance of 10 Ω/□) formed on one main surface thereof was prepared as the light-transmitting substrate 10 which is provided at the dye-sensitized photoelectric conversion body 20 side.

The porous semiconductor layer 13 made of a titanium dioxide layer serving as an electron transporter was formed on the light-transmitting conductive layer 11 of the glass substrate, by the following procedure. Firstly, acetylacetone was added to a TiO₂ anatase powder and the mixture was kneaded with deionized water to prepare a paste of titanium dioxide stabilized with a surfactant. The paste thus prepared was applied onto the light-transmitting conductive layer 11 at a constant speed using a doctor blade method and then sintered in atmospheric air at 450° C. for 20 minutes, to form a porous titanium dioxide layer.

A black dye (manufactured by Solaronix SA) was used as the dye 14, and acetonitrile and t-butanol (1:1 in terms of volume ratio) were used as a solvent into which the dye 14 was to be dissolved, to prepare a solution including the dye 14 dissolved therein. The glass substrate including the titanium dioxide layer formed thereon was immersed in the solution, to make the dye 14 supported on the titanium dioxide layer. The time period of the immersion was 24 hours, and the temperature of the glass substrate at that time was 24° C.

Then, an outer peripheral portion of the one main surface of the light-transmitting substrate 2 including the thin-film photoelectric conversion body 30 and the like formed thereon and an outer peripheral portion of the one main surface of the light-transmitting substrate 10 including the dye-sensitized photoelectric conversion body 20 formed thereon were stuck to each other with a thermoplastic adhesive (manufactured by DuPont, Trade Name “Bynel 4164”) and sealed airtight, to thereby form a film-like sealing member 8. An interval (corresponding to the thickness of the charge transport part 9) between the light-transmitting substrate 2 and the light-transmitting substrate 10 was 30 μm. At this time, a liquid electrolyte which will be mentioned later was contained in the titanium dioxide layer, and the liquid electrolyte swelled from a surface of the titanium dioxide layer due to surface tension. In this state, the light-transmitting substrate 2 and the light-transmitting substrate 10 were stuck to each other with the sealing member 8 interposed therebetween, to thereby load the electrolyte in the charge transport part 9. Thus, a laminated-type photoelectric conversion device 100 was prepared. An acetonitrile solution and tert-butyl pyridine (TBP) were added to a liquid electrolyte made of iodine (12) and lithium iodide (LiI), and prepared. A resultant was used as the charge transport part (electrolyte) 9. This laminated-type photoelectric conversion device 100 was evaluated for characteristics such as the photoelectric conversion efficiency.

The laminated-type photoelectric conversion device 100 thus obtained exhibited a relatively high short-circuit current density of 12.0 mA/cm² and a high open-circuit voltage (1.49V), under AM 1.5 and 100 mW/cm². The fill factor (FF) was 0.57, and the photoelectric conversion efficiency was 10.19%.

As described above, in the present example, a high photoelectric conversion efficiency could be realized.

1. A photoelectric conversion device comprising:
a light-transmitting conductive part including a light incident surface and a light output surface;
a semiconductor part formed on said light output surface;
an anti-reflection coating formed on said semiconductor part; and
a dye-sensitized photoelectric conversion body including a charge transport part and a dye that receives a charge from said charge transport part, said charge transport part being in contact with said anti-reflection coating,
wherein said anti-reflection coating has a bandgap larger than that of said semiconductor part.

2. The photoelectric conversion device according to claim 1, wherein said anti-reflection coating has conductivity.

3. The photoelectric conversion device according to claim 1, wherein said anti-reflection coating includes at least one of amorphous silicon carbide, amorphous silicon nitride, and titanium oxide.

4. The photoelectric conversion device according to claim 1, further comprising a catalyst layer formed on said anti-reflection coating,
wherein said charge transport part is in contact with said anti-reflection coating and said catalyst layer.

5. A photoelectric conversion device comprising:
a light-transmitting conductive part including a light incident surface and a light output surface;
a semiconductor part formed on said light output surface;
an anti-reflection coating formed on said semiconductor part; and
a dye-sensitized photoelectric conversion body including a charge transport part and a dye that receives a charge from said charge transport part, said charge transport part being in contact with said anti-reflection coating,
wherein a difference between a HOMO level and a LUMO level of said dye is smaller than bandgaps of said semiconductor part and said anti-reflection coating.

6. The photoelectric conversion device according to claim 5, wherein said anti-reflection coating has conductivity.

7. The photoelectric conversion device according to claim 5, wherein said anti-reflection coating includes at least one of amorphous silicon carbide, amorphous silicon nitride, and titanium oxide.

8. The photoelectric conversion device according to claim 5, further comprising a catalyst layer formed on said anti-reflection coating,
wherein said charge transport part is in contact with said anti-reflection coating and said catalyst layer.

9. A photovoltaic power generation device comprising the photoelectric conversion device according to claim 1,
wherein power generated by said photoelectric conversion device is supplied to a load.

10. A photovoltaic power generation device comprising the photoelectric conversion device according to claim 5,
wherein power generated by said photoelectric conversion device is supplied to a load.
